(19) United States
(12) Patent Application Publication
(10) Pub. No.: US 2014/0293559 A1
(43) Pub. Date: Oct. 2, 2014

(54) WIRING BOARD

(71) Applicant: NGK SPARK PLUG CO., LTD., Nagoya-shi (JP)

(72) Inventor: Kenji SUZUKI, Iwakura-shi (JP)

(73) Assignee: NGK SPARK PLUG CO., LTD., Nagoya-shi (JP)

(21) Appl. No.: 14/186,825

(22) Filed: Feb. 21, 2014

(30) Foreign Application Priority Data
Mar. 26, 2013 (JP) 2013-064349

(51) Int. Cl. H05K 1/02; H05K 1/18

(52) U.S. Cl. CPC H05K 1/0298; H05K 1/185
USPC 361/761

(57) ABSTRACT

A wiring board has a surface formed with a chip mounting area to which a chip component is mounted and includes embedded therein first and second multilayer capacitors, each of which has inner electrode layers laminated in a lamination direction. The first multilayer capacitors are embedded in a peripheral region of the wiring board immediately below a peripheral edge of the chip mounting area and a vicinity of the peripheral edge of the chip mounting area such that the lamination direction of the inner electrode layers of the first multilayer capacitors is perpendicular to the surface of the wiring board. The second multilayer capacitors are embedded in any other regions of the wiring board inside and outside the peripheral region such that the lamination direction of the inner electrode layers of at least one of the second multilayer capacitors is parallel to the surface of the wiring board.

### BACKGROUND OF THE INVENTION

The present invention relates to a wiring board having embedded therein multilayer capacitors.

There is known a wiring board for mounting thereon a chip component such as IC chip, which has a build-up layer formed with alternating insulating layers and conductor layers on a support layer, with multilayer capacitors embedded in the support layer, as disclosed in Japanese Laid-Open Patent Publication No. 2007-103789.

In the case of the wiring board mounting thereon the chip component and having embedded therein the multilayer capacitors, however, there is a possibility of the occurrence of cracks in the embedded multilayer capacitors. The occurrence of such cracks leads to a deterioration in the reliability of the wiring board.

### SUMMARY OF THE INVENTION

The present invention has been made in view of the above problem. It is accordingly an object of the present invention to provide a wiring board having embedded therein multilayer capacitors without loss of reliability.

According to an aspect of the present invention, there is provided a wiring board having a surface formed with a chip mounting area to which a chip component is mounted and comprising embedded therein first and second multilayer capacitors, each of which having a plurality of inner electrode layers laminated in a lamination direction, the first multilayer capacitors being embedded in a peripheral region of the wiring board immediately below a peripheral edge of the chip mounting area and a vicinity of the peripheral edge of the chip mounting area, the second multilayer capacitors being embedded in any other regions of the wiring board inside and outside the peripheral region, wherein the lamination direction of the inner electrode layers of the first multilayer capacitors is perpendicular to the surface of the wiring board; and wherein the lamination direction of the inner electrode layers at least one of the second multilayer capacitors is parallel to the surface of the wiring board.

The present inventor has found by reliability tests that, in the case of a wiring board having a surface formed with a chip mounting area to which a chip component is mounted and having embedded therein multilayer capacitors, each of which having a plurality of inner electrode layers laminated in a lamination direction, it is possible to prevent cracks from occurring, due to thermal shock, in the multilayer capacitors when the lamination direction of the inner electrode layers of the multilayer capacitors is perpendicular to the surface of the wiring board more effectively than when the lamination direction of the inner electrode layers of the multilayer capacitors is parallel to the surface of the wiring board.

Further, the present inventor has found that the crack occurs in the contact portion between the surface of the laminate of the inner electrode layers and dielectric layers and electrodes of the multilayer capacitor (see FIG. 3). The cause of the occurrence of such a crack is assumed that, as the multilayer capacitor is produced by laminating the dielectric layers printed with the inner electrode layers, and then, applying a pressure to the surface of the resulting layer laminate, an internal stress remains in the surface of the layer laminate.

Hence, it is conceivable to avoid the cracks by preventing the internal stress from remaining in the multilayer capacitors. In the case of the wiring board having the chip mounting area to which the chip component is mounted, the internal stress becomes maximum in a peripheral region of the wiring board immediately below a peripheral edge of the chip mounting area and a vicinity of the peripheral edge of the chip mounting area.

For these reasons, the first multilayer capacitors (embedded in the peripheral region where the internal stress becomes maximum) are arranged such that the lamination direction of the inner electrode layers of the first multilayer capacitors is perpendicular to the surface of the wiring board as mentioned above. It is therefore possible to effectively prevent the occurrence of cracks in the multilayer capacitor and improve the reliability of the wiring board.

Further, the second multilayer capacitors (embedded in any other regions inside and outside the peripheral region) are arranged such that the lamination direction of the inner electrode layers of at least one of the second multilayer capacitors is parallel to the surface of the wiring board in the present invention. With this arrangement, the electric field of the first multilayer capacitors and the electric field of the second multilayer capacitor or capacitors whose lamination direction of the inner electrode layers is parallel to the surface of the wiring board becomes perpendicular to each other. It is thus possible to avoid interference between these electric fields.

Preferably, the second multilayer capacitors may be arranged such that the lamination direction of the inner electrode layers of at least one of the second multilayer capacitors embedded in the region inside the peripheral region is parallel to the surface of the wiring board. With this arrangement, the electric field of the first multilayer capacitors and the electric field of the second multilayer capacitor or capacitors embedded in the region inside the peripheral region and whose lamination direction of the inner electrode layers is parallel to the surface of the wiring board become perpendicular to each other. It is thus possible to avoid constructive interference between these electric fields and prevent the chip component from being affected by the electric field of the multilayer capacitor or capacitors embedded immediately below the chip mounting area.

In order to more assuredly avoid and eliminate constructive interference between the electric field of the first multilayer capacitors and the electric fields of the second multilayer capacitors embedded in the region inside the peripheral region, the second multilayer capacitors may be arranged such that the lamination direction of all of any of the second multilayer capacitors embedded in the region inside the peripheral region is parallel to the surface of the wiring board.

The other objects and features of the present invention will also become understood from the following description.

### BRIEF DESCRIPTION OF THE DRAWINGS

FIG. 1 is a section view of a wiring board according to one embodiment of the present invention.

FIG. 2 is a plan view with a partial enlargement of the wiring board according to the one embodiment of the present invention

FIG. 3 is an enlarged cross section view of part of the wiring board according to the one embodiment of the present invention, which specifically shows the position of occurrence of cracks in the wiring board.

### DESCRIPTION OF THE EMBODIMENTS

The present invention will be described below with reference to the drawings.

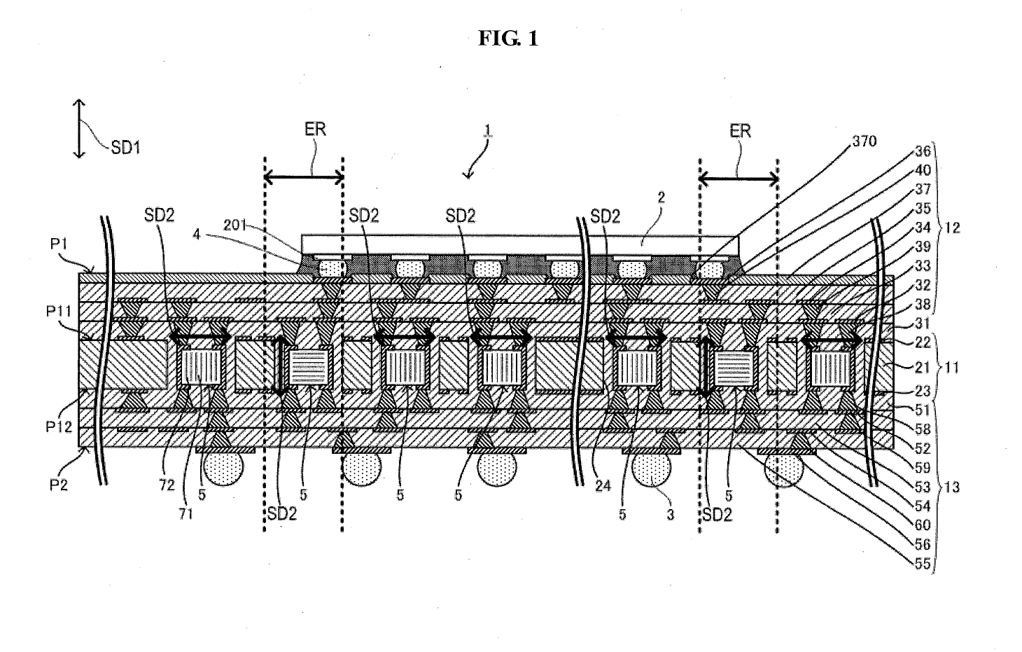

The following embodiment refers to a wiring board 1 that has two opposite main surfaces: one surface P1 formed with a chip mounting area to which an IC chip 2 (as a chip component) is mounted and the other surface P2 formed with a plurality of bumps 3 for connection between the IC chip 2 and another wiring board (such as motherboard; not shown) as shown in FIG. 1.

In the present embodiment, the wiring board 1 has a multilayer structure in which build-up layers 12 and 13 are laminated on both sides of a support layer 11 in a lamination direction SD1.

The support layer 11 includes a support substrate 21 and conductor layers 22 and 23. The support substrate 21 is formed in plate shape of e.g. an epoxy resin-impregnated glass fiber material and shows high rigidity. The conductor layers 22 and 23 are formed on opposite surfaces P11 and P12 of the support substrate 21, respectively.

As shown in FIG. 1, a plurality of capacitor accommodation holes 24 are formed through the support substrate 21 so that multilayer capacitors 5 are embedded in the capacitor accommodation holes 24, respectively.

The build-up layer 12 includes an insulating layer 31, a conductor layer 32, an insulating layer 33, a conductor layer 34, an insulating layer 35, a conductor layer 36 and a solder resist layer 37 laminated in this order on the conductor layer 22. Via conductors 38, 39 and 40 are formed through the insulating layers 31, 33 and 35, respectively, so as to extend along the lamination direction SD1. Thus, the conductor layer 22 and the chip capacitors 5 are electrically connected to the conductor layer 32 by the via conductors 38; the conductor layer 32 is electrically connected to the conductor layer 34 by the via conductors 39; and the conductor layer 34 is electrically connected to the conductor layer 36 by the via conductors 40. The outermost conductor layer 36 is arranged in openings 370 of the solder resist layer 37. A plurality of bumps 4 are formed on the outermost conductor layer 36 within the openings 370 of the solder resist layer 37 and are connected to connection terminals 201 of the IC chip 2.

The build-up layer 13 has an insulating layer 51, a conductor layer 52, an insulating layer 53, a conductor layer 54, an insulating layer 55 and a conductor layer 56 laminated in this order on the conductor layer 23. Via conductors 58, 59 and 60 are formed through the insulating layers 51, 53 and 55, respectively, so as to extend along the lamination direction SD1. Thus, the conductor layer 23 and the chip capacitors 5 are electrically connected to the conductor layer 52 by the via conductors 58; the conductor layer 52 is electrically connected to the conductor layer 54 by the via conductors 59; and the conductor layer 54 is electrically connected to the conductor layer 56 by the via conductors 60. The bumps 3 are formed on the outermost conductor layer 56 for connection to the above-mentioned another wiring board.

Each of the multilayer capacitors 5 has a plurality of dielectric layers 71 of e.g. dielectric ceramic material such as barium titanate and inner electrode layers 72 alternately laminated together in a lamination direction SD2. (Hereinafter, the lamination direction SD2 of the dielectric layers 71 and the inner electrode layers 72 is just referred to as “lamination direction SD2” for simplification purposes.) Each of the multilayer capacitors 5 also has electrodes 73 formed on opposite sides of the laminate of the dielectric layers 71 and the inner electrode layers 72 in the present embodiment.

In a peripheral region ER of the wiring board 1, the multilayer capacitors 5 (as first multilayer capacitors) are embedded such that the inner electrode layers 72 are oriented in a direction parallel to the surface P1 of the wiring board 1. In any other regions inside and outside the peripheral region ER, the multilayer capacitors 5 (as second multilayer capacitors) are embedded such that the inner electrode layers 72 are randomly oriented in directions perpendicular and parallel to the surface P1 of the wiring board 1.

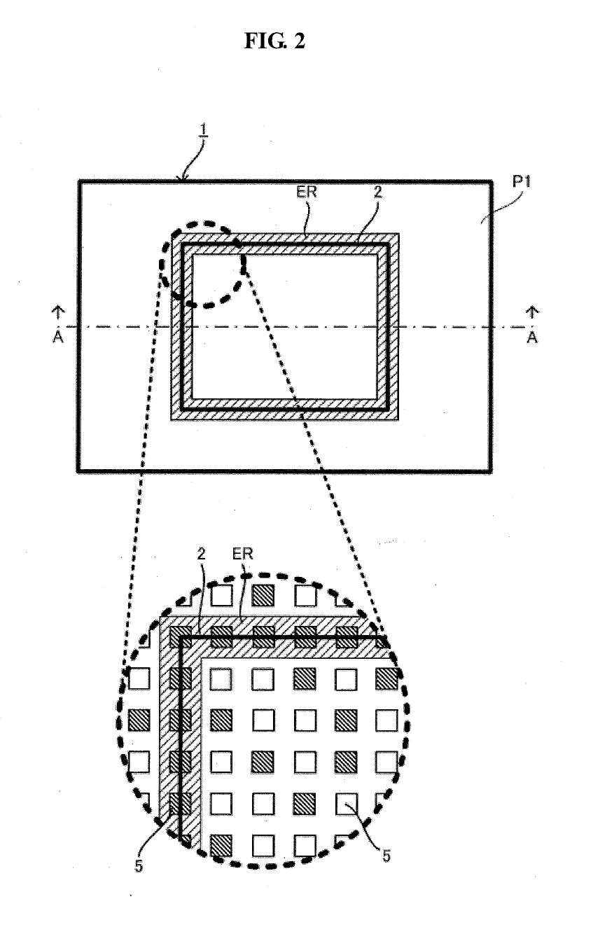

As shown by cross hatching in FIG. 2, the peripheral region ER is a frame-shaped region immediately below a peripheral edge of the chip mounting area and a vicinity of the peripheral edge of the chip mounting area. (FIG. 1 is a section view taken along line A-A of FIG. 2.) It is herein noted that:, in the partial enlargement of FIG. 2, the multilayer capacitors 5 whose inner electrode layers 72 are parallel to the surface P1 of the wiring board 1 (i.e. whose lamination direction SD2 is perpendicular to the surface P1 of the wiring board 1) are represented by hatched rectangles; and the multilayer capacitors 5 whose inner electrode layers 72 are perpendicular to the surface P1 of the wiring board 1 (i.e. whose lamination direction SD2 is parallel to the surface P1 of the wiring board 1) are represented by outlined rectangles.

The present inventor has found by reliability tests that it is possible to prevent cracks from occurring, due to thermal shock, in the multilayer capacitors 5 whose lamination direction SD2 is perpendicular to the surface P1 of the wiring board 1 more effectively than in the multilayer capacitors 5 whose lamination direction SD2 is parallel to the surface P1 of the wiring board 1. More specifically, it has been confirmed as a result of the reliability tests conducted by repeatedly applying thermal shock between low temperature (−45° C.) and high temperature (+150° C.) that: after 450 or more cycles of the thermal shock, there occurred cracks in the multilayer capacitors 5 whose lamination direction SD2 is parallel to the surface P1 of the wiring board 1; whereas there occurred no cracks in the multilayer capacitors 5 whose lamination direction SD2 is perpendicular to the surface P1 of the wiring board 1 even after 990 cycles of the thermal shock.

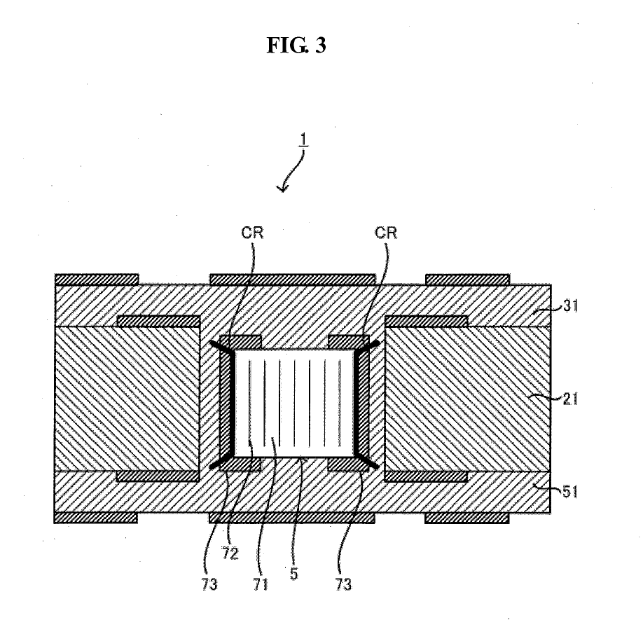

Further, the present inventor has found that the crack occurs in the contact portions between the electrodes 73 and the surface of the laminate of the dielectric layers 71 and the inner electrode layers 72 of the multilayer capacitor 5 as shown by reference symbol CR in FIG. 3. The cause of the occurrence of such a crack is assumed that, as the multilayer capacitor 5 is produced by laminating the dielectric layers 71 printed with the inner electrode layers 72, and then, applying a pressure to the surface of the resulting layer laminate, an internal stress remains in the surface of the layer laminate.

Hence, it is conceivable to avoid the cracks by preventing the internal stress from remaining in the multilayer capacitor 5. In the case of the wiring board 1 having the chip mounting area to which the IC chip 2 is mounted, the internal stress becomes maximum in the peripheral region ER.

For these reasons, the lamination direction SD2 of the multilayer capacitors 5 embedded in the peripheral region ER (where the internal stress becomes maximum) is set perpendicular to the surface P1 of the wiring board 1. It is therefore possible to effectively prevent the occurrence of cracks in the multilayer capacitors 5 and improve the reliability of the wiring board 1.

Further, the lamination direction SD2 of at least one of the multilayer capacitors 5 embedded in any other regions inside and outside the peripheral region ER is set parallel to the surface P1 of the wiring board 1. With this arrangement, the electric field of the multilayer capacitors 5 embedded in the peripheral region ER and the electric field of the multilayer capacitor or capacitors 5 embedded in any other regions inside and outside the peripheral region ER and whose lamination direction SD2 is parallel to the surface P1 of the wiring board 1 become perpendicular to each other. It is thus possible to avoid interference between these electric fields.

In particular, the lamination direction SD2 of at least one of the multilayer capacitors 5 embedded in the region inside the peripheral region ER is set parallel to the surface P1 of the wiring board 1 in the present embodiment. With this arrangement, the electric field of the multilayer capacitors 5 embedded in the peripheral region ER and the electric field of the multilayer capacitor or capacitors 5 embedded in the region inside the peripheral region ER and whose lamination direction SD2 is parallel to the surface P1 of the wiring board 1 become perpendicular to each other. It is thus possible to avoid constructive interference between these electric fields and prevent the IC chip 2 from being affected by the electric field of the multilayer capacitors 5 embedded immediately below the chip mounting area.

The entire contents of Japanese Patent Application No. 2013-064349 (filed on Mar. 26, 2013) are herein incorporated by reference.

Although the present invention has been described above with reference to the specific exemplary embodiment, the present invention is not limited to the above-described specific exemplary embodiment. Various modifications and variations of the embodiment described above will occur to those skilled in the art in light of the above teachings.

For example, the lamination direction SD2 of at least one of the multilayer capacitors 5 embedded in the region inside the peripheral region ER is set parallel to the surface P1 of the wiring board 1 in the above embodiment. Alternatively, the lamination direction SD2 of all of any of the multilayer capacitors 5 embedded in the region inside the peripheral region ER may be set parallel to the surface P1 of the wiring board 1 in order to more assuredly avoid and eliminate constructive interference between the electric field of the first multilayer capacitors 5 and the electric fields of the second multilayer capacitors 5 embedded in the region inside the peripheral region.

The scope of the invention is defined with reference to the following claims.

What is claimed is:

1. A wiring board having a surface formed with a chip mounting area to which a chip component is mounted and comprising embedded therein first and second multilayer capacitors, each of which having a plurality of inner electrode layers laminated in a lamination direction, the first multilayer capacitors being embedded in a peripheral region of the wiring board immediately below a peripheral edge of the chip mounting area and a vicinity of the peripheral edge of the chip mounting area, the second multilayer capacitors being embedded in any other regions of the wiring board inside and outside the peripheral region,
wherein the lamination direction of the inner electrode layers of the first multilayer capacitors is perpendicular to the surface of the wiring board; and
wherein the lamination direction of the inner electrode layers of at least one of the second multilayer capacitors is parallel to the surface of the wiring board.

2. The wiring board according to claim 1, wherein the lamination direction of the inner electrode layers of at least one of the second multilayer capacitors embedded in the region inside the peripheral region is parallel to the surface of the wiring board.

3. The wiring board according to claim 2, wherein the lamination direction of all of any of the second multilayer capacitors embedded in the region inside the peripheral region is parallel to the surface of the wiring board.
